(19) United States
(12) Patent Application Publication
(10) Pub. No.: US 2012/0263320 A1
(43) Pub. Date: Oct. 18, 2012

(54) Gain Control Device for an Amplifier and Related Methods, and an Audio Processing Device

(75) Inventors: Wenjing Wang, (US); Jing Cao, Rancho Santa Margarita, CA (US); Mingming Zhang, Beijing (CN)

(73) Assignee: BEIJING KT MICRO, LTD., Beijing (CN)

(21) Appl. No.: 13/444,667

(22) Filed: Apr. 11, 2012

(30) Foreign Application Priority Data
Apr. 15, 2011 (CN) 201110095108X

(51) Int. Cl. H03G 3/20

(52) U.S. Cl. 381/107; 330/136

(57) ABSTRACT

A gain control device for an amplifier and related methods, and an audio processing device are described herein. In one aspect, a gain control device for an amplifier includes: a receiver module configured to receive a control signal; a gain control module configured to control the gain of said amplifier based on said control signal. In another aspect, an audio processing device includes: a microphone; an audio player; and an amplifier, wherein said amplifier includes a gain control device configured to receive a control signal and to control the gain of said amplifier based on the received control signal. In another aspect, a method for controlling the gain of an amplifier includes: receiving a control signal; controlling the gain of said amplifier based on said control signal. The described methods and device reduce the application cost and size.

### RELATED APPLICATIONS INFORMATION

The application claims priority under 35 U.S.C. 119(a) to Chinese application number 201110095108X, filed on Apr. 15, 2011, which is incorporated herein by reference in its entirety as if set forth in full.

### BACKGROUND

1. Technical Field

The embodiments described herein relate to microelectronics, and more specifically, to a gain control device for an amplifier and related methods, and an audio processing device.

2. Related Art

A microphone is an energy conversion device that converts sound signals to electrical signals. Since the electrical signals output by the microphone are very weak, it is necessary to adopt an amplifier to amplify the electrical signals.

For Some devices, different multiples of amplification are required for the electrical signals. For example, for a telephone, the multiple of amplification in a hands-free mode is different from the multiple of amplification in a normal answering mode. As a result, these devices use either multiple amplifiers to amplify the electrical signals output by the microphone at different multiples or use multiple microphones of different gains. Under the existing technologies, the microphone and the amplifier is usually integrated in one chip, thus increasing both the application cost and size.

### SUMMARY

A gain control device for an amplifier and related methods, and an audio processing device are described herein. The described methods and device reduce the application cost and size.

In one aspect, a gain control device for an amplifier includes: a receiver module configured to receive a control signal; and a gain control module configured to control the gain of said amplifier based on said control signal.

In another aspect, an audio processing device includes: a microphone; an audio player; and an amplifier, wherein said amplifier includes a gain control device configured to receive a control signal and to control the gain of said amplifier based on the received control signal.

In another aspect, a gain control method for an amplifier includes: receiving a control signal; and controlling the gain of said amplifier based on said control signal.

In the present embodiments, after receiving a control signal, the gain of the amplifier may be controlled based on the received control signal. Since the gain of the amplifier is tunable, only one amplifier may amplify the electrical signals output by the microphone to different multiples of amplification, thus avoiding adopting multiple amplifiers to amplify the microphone output signal at different multiples or adopting multiple microphones of different gains under the existing technologies. Moreover, the microphone and the amplifier are usually integrated in one chip, thus reducing both the application cost and size.

These and other features, aspects, and embodiments are described below in the section entitled “Detailed Description.”

### BRIEF DESCRIPTION OF THE DRAWINGS

Features, aspects, and embodiments are described in conjunction with the attached drawings, in which:

FIG. 1 is a schematic diagram showing a gain control device for an amplifier according to a first embodiment;

FIG. 2 is a schematic diagram showing a gain control device for an amplifier according to a second embodiment;

FIG. 3 is a circuit diagram showing the amplifier in FIG. 2;

FIG. 4 is a schematic diagram showing an audio processing device according to an embodiment;

FIG. 5 is a flow chart showing a method for controlling the gain of an amplifier according to a first embodiment;

FIG. 6 is a flow chart showing a method for controlling the gain of an amplifier according to a second embodiment.

### DETAILED DESCRIPTION

Referring now to the drawings, a description will be made herein of embodiment herein.

FIG. 1 is a schematic diagram showing a gain control device for an amplifier according to a first embodiment. The device may include a receiver module 11 and a gain control module 12, the gain control module 12 may be configured to connect with the receiver module 11.

In particular, the receiver module 11 may be configured to receive a control signal; the gain control module 12 may be configured to control the gain of the amplifier based on the control signal. Specifically, the control signal may be input from an external input.

In one embodiment, after the receiver module 11 receives a control signal, the gain control module 12 may be configured to control the gain of the amplifier based on the control signal. Since the gain of the amplifier is tunable, one amplifier may amplify the electrical signal output by the microphone at different multiples, thus avoiding the use of multiple amplifiers to amplify the electrical signal output by the microphone at different multiples or the use of multiple microphones of different gains under the existing technologies. Moreover, the microphone and amplifier are usually integrated in a chip, thus reducing the application cost and size.

FIG. 2 is a schematic diagram showing a gain control device for an amplifier according to a second embodiment. The differences between FIG. 2 and FIG. 1 may include: the gain control module 12 may include a comparator unit 121 and a gain control unit 122, the comparison unit 121 may be configured to connect with the receiver module 11, and the gain control unit 122 may be configured to connect with the comparator unit 121.

In particular, the comparator unit 121 may be configured to compare the control signal with a predetermined threshold; the gain control unit 122 may be configured to control the gain of the amplifier based on the comparison result of the comparator unit.

In one embodiment, the predetermined threshold may be a predetermined threshold, when the control signal is greater than or equal to the predetermined threshold, the gain control unit 122 may control the gain of the amplifier to be a first gain. For example, the first gain is 20 dB, when the control signal is less than the predetermined threshold, the gain control unit 122 may control the gain of the amplifier to be a second gain, for example: the second gain is 0 dB.

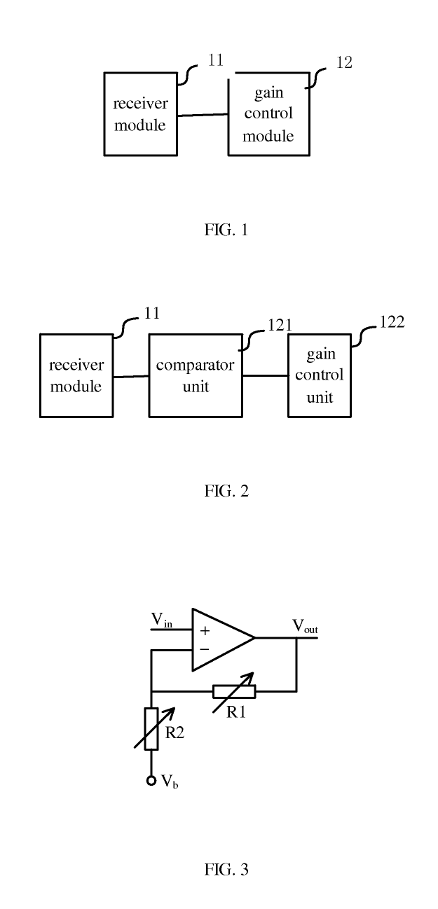

FIG. 3 is a circuit diagram showing the amplifier in FIG. 2. The amplifier may include an op-amp 123, a first tunable resistor R1, a second tunable resistor R2. The negative input of the op-amp 123 may be configured to be connected between the first tunable resistor R1 and the second tunable resistor R2, the first tunable resistor R1 may be configured to connect with a DC bias voltage Vb, the second tunable resistor R2 may be configured to connect with the output of the op-amp 123, the gain G of the amplifier may be calculated according to the following formula:

$$G = \frac{{V}_{out}}{{V}_{i n}} = 1 + \frac{R 1}{R 2}$$

In particular, Vᵢₙ is the input voltage of the amplifier, Vₒᵤₜ is the output voltage of the amplifier. The operation of the amplifier illustrated in FIG. 3 may include: the receiver module 11 may receive the control signal, the comparator unit 121 may compare the control signal with a predetermined threshold, when the control signal is less than the predetermined threshold, the gain control unit 122 may adjust the resistance of the tunable resistor R1 and the second tunable resistor R2 to make the gain G of the amplifier be 0 dB; when the control signal is greater than or equal to the predetermined threshold, the gain control unit 122 may adjust the resistance of the first tunable resistor R1 and the second tunable resistor R2 to make the gain G of the amplifier be 20 dB.

In one embodiment, the predetermined threshold may include two or more predetermined thresholds. In the instance of two predetermined thresholds, for example, the two predetermined thresholds may include a first predetermined threshold and a second predetermined threshold, the first predetermined threshold is greater than the second predetermined threshold. When the control signal is greater than the first predetermined threshold, the gain control unit 122 may control the gain of the amplifier to be a first gain, for example, the first gain is 20 dB; when the control signal is less than or equal to the first predetermined threshold and greater than the second predetermined threshold, the gain control unit 122 may control the gain of the amplifier to be a second gain, for example, the second gain is 10 dB; when the control signal is less than or equal to the second threshold, the gain control unit 11 may control the gain of the amplifier to be a third gain, for example, the third gain is 0 dB.

In this embodiment, after the receiver module 11 receives the control signal, the comparator unit 121 may be configured to compare the control signal with the predetermined threshold, the gain control unit 122 may be configured to control the gain of the amplifier according to the comparison result of the comparator unit. Since the gain of the amplifier is tunable, one amplifier may amplify the electrical signal output by the microphone at different multiples, thus avoiding the use of multiple amplifiers to amplify the electrical signal output by the microphone at different multiples or the use of multiple microphones of different gains under the existing technologies. Moreover, the microphone and amplifier are usually integrated in a chip, thus reducing the application cost and size.

FIG. 4 is a schematic diagram showing an audio processing device. The audio processing device may include a microphone 31, an amplifier 32, and an audio player 33. The amplifier 32 may include a gain control unit 321. The amplifier 32 may be configured to connect to the microphone 31, the audio player 33 may be configured to connect to the amplifier 32.

The microphone 31 may be configured to convert a sound signal sampled to an electrical signal, the amplifier 32 may be configured to amplify the electrical signal, the audio player 33 may be configured to convert the amplified electrical signal into sound. The gain control unit 321 may be configured to receive a control signal and to control the gain of the amplifier based on the control signal.

It should be noted that the gain control unit 321 may include the foregoing gain control units for the amplifier in the aforementioned embodiments.

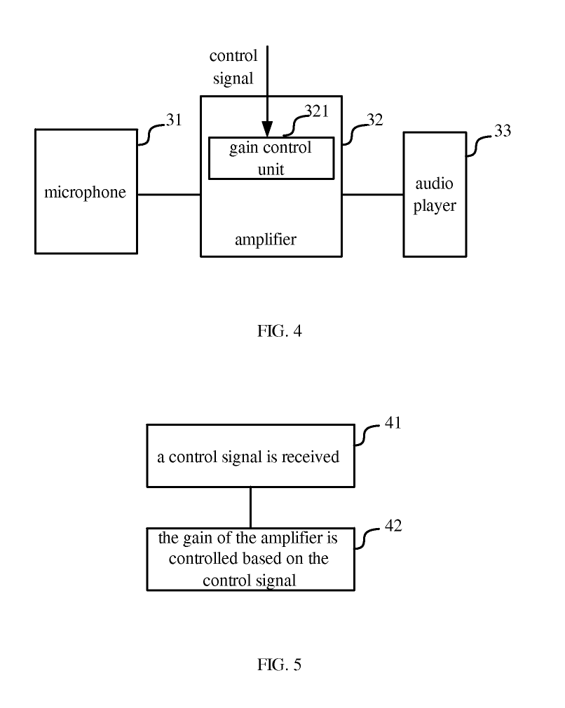

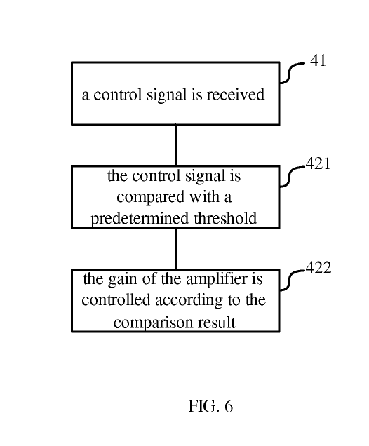

FIG. 5 is a flow chart showing a method for controlling the gain of an amplifier according to a first embodiment. The method may include the following steps:

In step 41, a control signal is received;

specifically, the control signal is from an external input;

In step 42, the gain of the amplifier is controlled based on the control signal.

In this embodiment, after receiving the control signal, the control signal may control the gain of the amplifier. Since the gain of the amplifier is tunable, one amplifier may amplify the microphone output signal at different multiples, avoiding the use of multiple amplifiers to amplify the electrical signal output by the microphone at different multiples or the use of multiple microphones of different gains under the existing technologies. Moreover, the microphone and amplifier are usually integrated in a chip, thus reducing the application cost and size.

FIG. 6 is a flow chart showing a method for controlling the gain of an amplifier according to a second embodiment. The differences from FIG. 5 may include the following steps in step 42:

In step 421, the control signal is compared with a predetermined threshold;

In step 422, the gain of the amplifier is controlled according to the comparison result.

In one embodiment, the predetermined threshold may include a predetermined threshold, when the control signal is greater than or equal to the predetermined threshold, the gain of the amplifier is controlled to be a first gain. For example, the first gain is 20 dB, when the control signal is less than the predetermined threshold, the gain of the amplifier is controlled to be a second gain for example: the second gain is 0 dB.

In another embodiment, the predetermined threshold may include two or more predetermined thresholds. In instance of two predetermined thresholds, the two predetermined thresholds may include a first predetermined threshold and a second predetermined threshold, the first predetermined threshold is greater than the second predetermined threshold. When the control signal is greater than the first predetermined threshold, the gain of the amplifier is controlled to be a first gain, for example, the first gain is 20 dB; when the control signal is less than or equal to the first predetermined threshold and greater than the second predetermined threshold, the gain of the amplifier is controlled to be a second gain, for example, the second gain is 10 dB; when the control signal is less than or equal to the second threshold, the gain of the amplifier is controlled to be a third gain, for example, the third gain is 0 dB.

In this embodiment, after receiving the control signal, the control signal may be compared with the predetermined threshold to control the gain of the amplifier according to the comparison result, so the gain of the amplifier is tunable. Since the gain of the amplifier is tunable, one amplifier may amplify the electrical signal output by the microphone at different multiples, avoiding the use of multiple amplifiers to amplify the microphone output signal at different multiples or the use of multiple microphones of different gains under the existing technologies. Moreover, the microphone and amplifier are usually integrated in a chip, thus reducing the application cost and size.

While certain embodiments have been described above, it will be understood that the embodiments described are by way of example only. Accordingly, the systems and methods described herein should not be limited based on the described embodiments. Rather, the systems and methods described herein should only be limited in light of the claims that follow when taken in conjunction with the above description and accompanying drawings.

What is claimed is:

1. A gain control device for an amplifier including:
a receiver module configured to receive a control signal; and
a gain control module configured to control the gain of said amplifier based on said control signal.

2. The gain control device according to claim 1, wherein the gain control module includes:
a comparator unit configured to compare the control signal with a predetermined threshold; and
a gain control unit configured to control the gain of the amplifier based on the comparison result of the comparator unit.

3. The gain control device according to claim 2, wherein the gain control unit is configured to control the gain of the amplifier to be a first gain if the control signal is greater than or equal to the predetermined threshold, or to be a second gain if the control signal is less than the predetermined threshold.

4. An audio processing device including:
a microphone;
an audio player; and
an amplifier, wherein the amplifier includes a gain control device configured to receive a control signal and to control the gain of the amplifier based on the control signal.

5. The audio processing device according to claim 4, wherein the gain control device includes the gain control device according to claim 1.

6. The audio processing device according to claim 4, wherein the gain control device includes the gain control module according to claim 2.

7. The audio processing device according to claim 4, wherein the gain control device includes the gain control unit according to claim 3.

8. A method for controlling the gain of an amplifier including:
receiving a control signal; and
controlling the gain of the amplifier based on the control signal.

9. The method of claim 8, wherein controlling the gain of the amplifier based on the control signal comprising:
comparing the control signal with a predetermined threshold; and
controlling the gain of the amplifier based on the comparison result.

10. The method of claim 9, wherein controlling the gain of the amplifier based on the result of comparison comprising:
controlling the gain of the amplifier to be a first gain if the control signal is greater than or equal to the predetermined threshold; or
controlling the gain of the amplifier to be a second gain if the control signal is less than the predetermined threshold.
